(19) United States
(12) Patent Application Publication
(10) Pub. No.: US 2021/0009860 A1
(43) Pub. Date: Jan. 14, 2021

(54) OPTICALLY CLEAR ADHESIVE AND METHOD OF MANUFACTURING SAME, AND DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventor: Chunmei HE, Wuhan, Hubei (CN)

(21) Appl. No.: 16/630,449

(22) PCT Filed: Oct. 18, 2019
(86) PCT No.: PCT/CN2019/111803

§ 371 Date: Jan. 12, 2020

(30) Foreign Application Priority Data
Jul. 8, 2019 (CN) 201910608817.X

(51) Int. Cl. C09J 7/10; B32B 7/12; C09J 7/30; C09J 9/00; H01L 51/52

(52) U.S. Cl. CPC C09J 7/10; B32B 7/12; C09J 7/30; C09J 9/00; H01L 51/5237; C09J 2467/005; C09J 2475/00; C09J 2203/326; C09J 2423/045; C09J 2423/105; B32B 2457/208

(57) ABSTRACT

The invention provides for an optically clear adhesive (OCA), a display panel, and a method of manufacturing the OCA. The OCA includes an OCA layer and a polyurethane resin layer which are disposed in a stack. The polyurethane resin layer mixes with the OCA layer. The method includes a plurality of steps of: providing a lower release film, manufacturing the OCA layer, and manufacturing the polyurethane resin layer. The display panel includes a backplate layer, a display layer, a touch control layer, a polarizer, and a flexible plate which are sequentially disposed on each other. The OCA is disposed between the backplate layer and the display layer and/or is disposed between the display layer and the touch control layer and/or is disposed between the touch control layer and the polarizer and/or is disposed between the polarizer and the flexible plate.

### FILED

The present disclosure relates to a field of display and, more particularly, relates to an optically clear adhesive and a method of manufacturing same, and a display panel.

### BACKGROUND

Organic light-emitting diodes (OLEDs) are also known as organic light-emitting devices or organic light-emitting conductors. The OLEDs has many characters such as self-luminescence, wide viewing angles, low power consumption, fast response times, and flexibility, which have been regarded as next generation display technology since they were found.

With emergence of OLEDs having a polyimide (PI) substrate, market demands for flexibility of display devices are becoming higher and higher. Take, for instance, foldable phones, material of the foldable phones must have not only flexibility and an ability to be folded but also have a certain hardness. However, conventional plate glasses cannot satisfy the above requirements. In the current market, most covering films are made by coating a hard coating layer on a transparent PI film. The hard coating layer has high hardness but low flexibility. Although the covering film can reach a hardness above 9H, a hardness of an OLED module display panel is decreased due to deformation of an optically clear adhesive (OCA) in a structure of the OLED module display panel.

Conventional OCAs are very soft with a Young's modulus of only about 40 kpa. Thickness and hardness of material of the covering film are much less than that of glass because the covering film must be foldable. When we use a 7H pencil scraping a 6H covering film, a scratch and an indentation are left on the 6H covering layer. A surface of the covering film 6 is harmed and is hard to be recovered. When we use a 6H pencil scraping the 6H covering film, a scratch and an indentation are left on the 6H covering layer because a hardness of the 6H covering film is too low and an OCA is too soft. The scratch indicates that a surface of the 6H covering film is harmed, which can be improved only by increasing hardness of the covering film 6H. However, the indentation indicates that the OCA is too soft. Therefore, if the indentation can be rapidly recovered, we can infer that hardness of the covering film is 6H.

Consequently, how to ensure that the OCA can be rapidly recovered under external force is a technical problem that desired to be solved.

### SUMMARY

One aspect of the present disclosure is to provide an optically clear adhesive (OCA) and a method of manufacturing same, and a display panel to ensure the OCA can be rapidly recovered under external force, to reduce indentation recovery time, and to improve a hardness of a surface of the display panel.

To solve the above problem, one embodiment of the present disclosure provides an OCA, including an OCA layer and a polyurethane resin layer which are formed in a stack. Specifically, the polyurethane resin layer is disposed on the OCA layer. The polyurethane resin layer mixes with the OCA layer.

Furthermore, material of the OCA layer includes a thermosetting OCA and/or an ultraviolet curing OCA.

Furthermore, a thickness of the polyurethane resin layer is less than a thickness of the OCA layer.

Furthermore, a thickness of the polyurethane resin layer is less than 5 82 m.

An embodiment of the present disclosure provides a method of manufacturing the above OCA, including a plurality of steps of: providing a lower release film; manufacturing the OCA layer, wherein the step of manufacturing the OCA layer includes a step of coating the OCA layer on the lower release film; manufacturing the polyurethane resin layer. The step of manufacturing the polyurethane resin layer includes a plurality of steps of: coating polyurethane on the OCA layer; foaming the polyurethane, wherein the polyurethane mixes with the OCA layer in a contact area thereof to form the polyurethane resin layer after foaming the polyurethane.

Furthermore, a step between the step of manufacturing the OCA layer and the step of manufacturing the polyurethane resin layer includes a pre-curing step, wherein the pre-curing step is to pre-cure the OCA layer by heating or illuminating ultraviolet light.

Furthermore, a step after the step of manufacturing the polyurethane resin layer includes a curing step, wherein the curing step is to cure the polyurethane resin layer by heating or illuminating ultraviolet light.

Furthermore, the lower release film is one of a polyethylene terephthalate (PET) release film, a polyethylene (PE) release film, an orientated polypropylene (OPP) release film, a biaxially-oriented polyethylene terephthalate (BOPET) release film, and a biaxially oriented polypropylene (BOPP) release film.

One embodiment of the present disclosure provides a display panel, including a backplate layer, a display layer, a touch control layer, a polarizer, and a flexible plate which are disposed in a stack. The OCA is disposed between the backplate layer and the display layer; and/or is disposed between the display layer and the touch control layer; and/or is disposed between the touch control layer and the polarizer; and/or is disposed between the polarizer and the flexible plate.

Furthermore, the flexible plate includes a substrate of the flexible plate and a hard coating layer disposed on the substrate of the flexible plate. The substrate of the flexible plate is disposed on the polarizer.

Regarding the beneficial effects of the present disclosure, an optically clear adhesive (OCA) and a method of manufacturing same, and a display panel are provided to ensure the OCA can be rapidly recovered under external force, to reduce indentation recovery time, and to improve hardness of a surface of the display panel.

### DESCRIPTION OF DRAWINGS

FIG. 1 is a schematic structural diagram of an optically clear adhesive (OCA) according to one embodiment of the present disclosure.

FIG. 2 is a flowchart showing a manufacturing process of an OCA according to one embodiment of the present disclosure.

FIG. 3 is a schematic structural diagram showing an OCA disposed between a backplate layer and a display layer of a display panel according to one embodiment of the present disclosure.

FIG. 4 is a schematic structural diagram showing an OCA disposed between a display layer, a touch control layer, and a polarizer of a display panel according to one embodiment of the present disclosure.

FIG. 5 is a schematic structural diagram showing an OCA disposed between layers of a display panel according to one embodiment of the present disclosure.

### DETAILED DESCRIPTION

In the description of the present disclosure, unless specified or limited otherwise, it should be noted that, a structure in which a first feature is “on” or “beneath” a second feature may include an embodiment in which the first feature directly contacts the second feature and may also include an embodiment in which an additional feature is formed between the first feature and the second feature so that the first feature does not directly contact the second feature. Furthermore, a first feature “on,” “above,” or “on top of” a second feature may include an embodiment in which the first feature is right “on,” “above,” or “on top of” the second feature and may also include an embodiment in which the first feature is not right “on,” “above,” or “on top of” the second feature, or just means that the first feature has a sea level elevation greater than the sea level elevation of the second feature. While first feature “beneath,” “below,” or “on bottom of” a second feature may include an embodiment in which the first feature is right “beneath,” “below,” or “on bottom of” the second feature and may also include an embodiment in which the first feature is not right “beneath,” “below,” or “on bottom of” the second feature, or just means that the first feature has a sea level elevation less than the sea level elevation of the second feature. In the present disclosure, the same or corresponding components are denoted by the same reference numerals and are not related to the figure number. Throughout the specification, when terms “first”, “second”, etc. are used to describe various components, these components are not necessarily limited to the above. The above terms are only used to distinguish one component from another.

The present disclosure further provides an optically clear adhesive (OCA) including an OCA layer and a polyurethane resin layer disposed on the OCA layer. The OCA layer mixes with the polyurethane resin layer.

Preferably, material of the OCA layer includes a thermosetting OCA and/or an ultraviolet curing OCA.

Preferably, a thickness of the polyurethane resin layer is less than a thickness of the OCA layer.

Preferably, a thickness of the polyurethane resin layer is less than 5 μm.

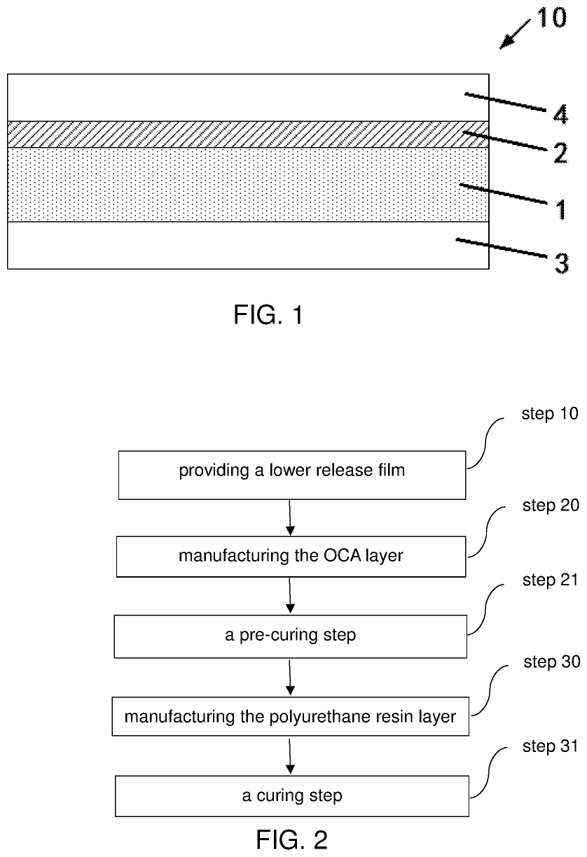

Referring to FIG. 1, one embodiment of the present disclosure provides an OCA 10 including an OCA layer 1 and a polyurethane resin layer 2 which are disposed in a stack. Typically, the OCA 10 is disposed on a lower release film 3 which is used as a carrier. Specifically, the OCA layer 1 is disposed on the lower release film 3, and the polyurethane resin layer 2 is disposed on the OCA layer 1. The polyurethane resin layer 2 mixes with the OCA layer 1. Of course, an upper release film 4, which has protective effects, can further be disposed on the polyurethane resin layer 2.

It should be noted, the upper release film 4 and the lower release film 3 must be peeled of before using the OCA 10.

In the present embodiment, the upper release film 4 and the lower release film 3 are one of a polyethylene terephthalate (PET) release film, a polyethylene (PE) release film, an orientated polypropylene (OPP) release film, a biaxially-oriented polyethylene terephthalate (BOPET) release film, and a biaxially oriented polypropylene (BOPP) release film. Thicknesses of the upper release film 4 and the lower release film 3 are in the range of 40 to 60 μm (preferred 50 μm). Peel forces of the upper release film 4 and the lower release film 3 are in the range of 5 to 12 g, so the outermost layer will not easily be separated, which can better protect the OCA 10.

In the present embodiment, material of the OCA layer includes a thermosetting OCA and/or an ultraviolet curing OCA.

In the present embodiment, a thickness of the polyurethane resin layer is less than a thickness of the OCA layer.

In the present embodiment, a thickness of the polyurethane resin layer is less than 5 μm. Because an object of adding the polyurethane is to increase recovery speed of deformation, thickness of the polyurethane does not need to be too thick. Depth of the indentation caused by the pencil is less than 5 μm, so the thickness of the polyurethane is limited to less than 5 μm to ensure a bendability of the polyurethane.

The present disclosure further provides a method of manufacturing the OCA, including a plurality of steps of: providing a lower release film; manufacturing the OCA layer, wherein the step of manufacturing the OCA layer includes a step of coating the OCA layer on the lower release film; manufacturing the polyurethane resin layer. The step of manufacturing the polyurethane resin layer includes a plurality of steps of: coating polyurethane on the OCA layer, and then foaming the polyurethane, wherein the polyurethane mixes with the OCA layer in a contact area thereof to form the polyurethane resin layer after foaming the polyurethane.

Preferably, a step between the step of manufacturing the OCA layer and the step of manufacturing the polyurethane resin layer includes a pre-curing step, wherein the pre-curing step is to pre-cure the OCA layer by heating or illuminating ultraviolet light.

Preferably, a step after the step of manufacturing the polyurethane resin layer includes a curing step, wherein the curing step is to cure the polyurethane resin layer by heating or illuminating ultraviolet light.

Preferably, the lower release film is one of a polyethylene terephthalate (PET) release film, a polyethylene (PE) release film, an orientated polypropylene (OPP) release film, a biaxially-oriented polyethylene terephthalate (BOPET) release film, and a biaxially oriented polypropylene (BOPP) release film.

Referring to FIGS. 1 and 2, an embodiment of the present disclosure provides a method of manufacturing an OCA 10, including a plurality of steps of: step 10: providing a lower release film 3; step 20: manufacturing the OCA layer 1, wherein the step of manufacturing the OCA layer 1 includes a step of coating the OCA layer 1 on the lower release film 3; step 30: manufacturing the polyurethane resin layer 2. The step of manufacturing the polyurethane resin layer 2 includes a plurality of steps of: coating polyurethane on the OCA layer 1 and then foaming the polyurethane, wherein the polyurethane mixes with the OCA layer in a contact area thereof to form the polyurethane resin layer 2 after foaming the polyurethane. By the above steps, the polyurethane can be doped in the OCA layer 1, thereby ensuring that the OCA 10 can be rapidly recovered under external force.

Furthermore, an upper release film 4, which has protective effects, can further be disposed on the polyurethane resin layer 2. The upper release film 4 and the lower release film 3 are one of a polyethylene terephthalate (PET) release film, a polyethylene (PE) release film, an orientated polypropylene (OPP) release film, a biaxially-oriented polyethylene terephthalate (BOPET) release film, and a biaxially oriented polypropylene (BOPP) release film. Thicknesses of the upper release film 4 and the lower release film 3 are in the range of 40 to 60 μm (preferred 50 μm). Peel forces of the upper release film 4 and the lower release film 3 are in the range of 5 to 12 g, so the outermost layer will not easily be separated, which can better protect the OCA 10.

Referring to FIG. 2, in the present disclosure, a step between the step of manufacturing the OCA layer 1 and the step of manufacturing the polyurethane resin layer 2 further includes: step 21: a pre-curing step, wherein the pre-curing step is to pre-cure the OCA layer by heating or illuminating ultraviolet light. By setting the pre-curing step, manufacturing time can be reduced, and working efficiency can be effectively improved.

Referring to FIG. 2, in the present embodiment, a step after the step of manufacturing the polyurethane resin layer 2 further includes: step 31: a curing step, wherein the curing step is to cure the polyurethane resin layer 2 by heating or illuminating ultraviolet light.

The present disclosure provides a display panel, including a backplate layer, a display layer, a touch control layer, a polarizer, and a flexible plate which are disposed in a stack. The OCA is disposed between the backplate layer and the display layer; and/or is disposed between the display layer and the touch control layer; and/or is disposed between the touch control layer and the polarizer; and/or is disposed between the polarizer and the flexible plate.

Preferably, the flexible plate includes a substrate of the flexible plate and a hard coating layer disposed on the substrate of the flexible plate. The substrate of the flexible plate is disposed on the polarizer. It should be noted, any optical and transparent material can be material of the substrate of the flexible plate.

One embodiment of the present disclosure provides a display panel 100, including a backplate layer 20, a display layer 30, a touch control layer 40, a polarizer, 50 and a flexible plate 60 which are disposed in a stack. The flexible plate 60 includes a substrate 61 of the flexible plate 60 and a hard coating layer 62 disposed on the substrate 61 of the flexible plate 60. The substrate 61 of the flexible plate 60 is disposed on the polarizer 50.

Detailed embodiments are described as follows:

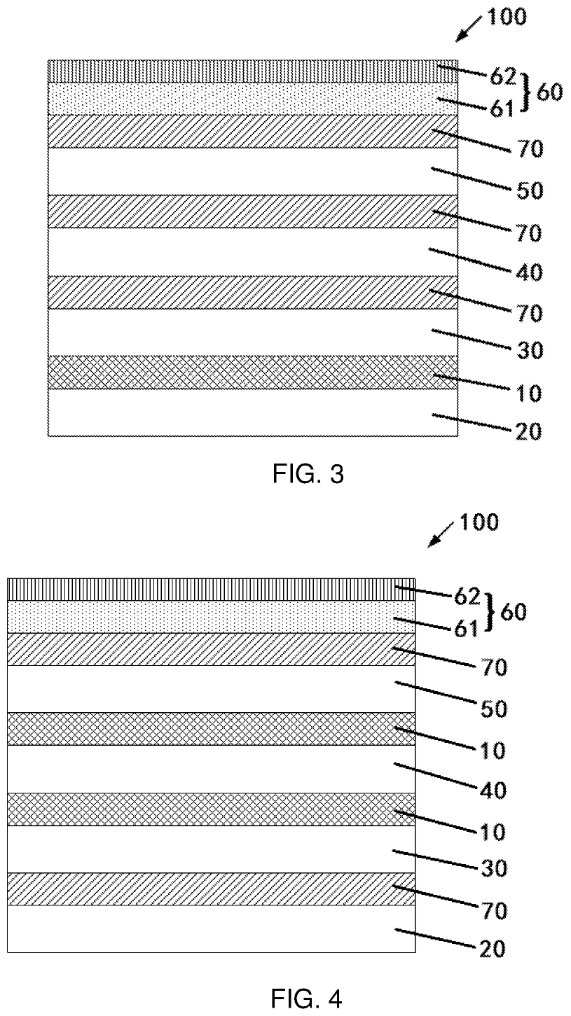

Referring to FIG. 3, some layers of the display panel 100 have the OCA 10 disposed therebetween, the other layers of the display panel 100 have OCA 70 disposed therebetween. In detail, the OCA 10 of the present disclosure is disposed between the backplate layer 20 and the display layer 30. A conventional OCA 70 may be used for adhesive other layers of the display panel 100.

Referring to FIG. 4, the OCA 10 of the present disclosure is disposed between the display layer 30, the touch control layer 40, and the polarizer 50. The conventional OCA 70 is used for adhesive other layers of the display panel 100.

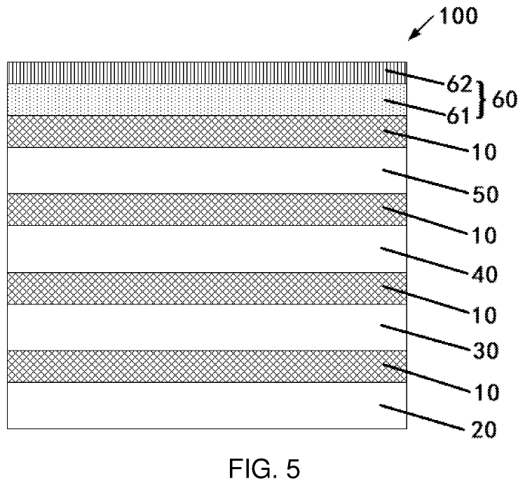

Referring to FIG. 5, the OCA 10 of the present disclosure may be disposed between layers of the display panel 100.

Consequently, in the display panel 100, the OCA 10 can be disposed between any adjacent layers or can be disposed between at least one adjacent layers, or can be disposed between every adjacent layers. The embodiments of the above cases are all within the scope of protection of the present disclosure, and will not be listed again here.

Regarding the beneficial effects of the present disclosure, an OCA and a method of manufacturing same, and a display panel are provided to ensure the OCA can be rapidly recovered under external force, to reduce indentation recovery time, and to improve hardness of a surface of the display panel.

The above are merely preferred embodiments of the present disclosure. It is understood that many changes and modifications to the described embodiment can be carried out without departing from the scope and the spirit of the disclosure that is intended to be limited only by the appended claims.

What is claimed is:

1. An optically clear adhesive (OCA), comprising:
an OCA layer; and
a polyurethane resin layer disposed on the OCA layer;
wherein the polyurethane resin layer mixes with the OCA layer.

2. The OCA of claim 1, wherein material of the OCA layer comprises a thermosetting OCA and/or an ultraviolet curing OCA.

3. The OCA of claim 1, wherein a thickness of the polyurethane resin layer is less than a thickness of the OCA layer.

4. The OCA of claim 1, wherein a thickness of the polyurethane resin layer is less than 5 μm.

5. A method of manufacturing the OCA of claim 1, comprising a plurality of steps of:
providing a lower release film;
manufacturing the OCA layer, wherein the step of manufacturing the OCA layer is to coat the OCA layer on the lower release film;
manufacturing the polyurethane resin layer, wherein the step of manufacturing the polyurethane resin layer is to coat polyurethane on the OCA layer, and then foam the polyurethane, wherein the polyurethane mixes with the OCA layer in a contact area thereof to form the polyurethane resin layer after the OCA layer is foamed.

6. The method of claim 5, wherein a step between the step of manufacturing the OCA layer and the step of manufacturing the polyurethane resin layer comprises:
a pre-curing step, wherein the pre-curing step is to pre-cure the OCA layer by heating or illuminating ultraviolet light.

7. The method of claim 5, wherein a step after the step of manufacturing the polyurethane resin layer comprises:
a curing step, wherein the curing step is to cure the polyurethane resin layer by heating or illuminating ultraviolet light.

8. The method of claim 6, wherein the lower release film is one of a polyethylene terephthalate (PET) release film, a polyethylene (PE) release film, an orientated polypropylene (OPP) release film, a biaxially-oriented polyethylene terephthalate (BOPET) release film, and a biaxially oriented polypropylene (BOPP) release film.

9. A display panel, comprising a backplate layer, a display layer, a touch control layer, a polarizer, and a flexible plate which are disposed in a stack;
wherein the OCA of claim 1 is disposed between the backplate layer and the display layer; and/or
wherein the OCA of claim 1 is disposed between the display layer and the touch control layer; and/or
wherein the OCA of claim 1 is disposed between the touch control layer and the polarizer; and/or
wherein the OCA of claim 1 is disposed between the polarizer and the flexible plate.

10. The display panel of claim 9, wherein the flexible plate comprises a substrate of the flexible plate and a hard coating layer disposed on the substrate of the flexible plate; and
wherein the substrate of the flexible plate is disposed on the polarizer.
